(19) United States
(12) Patent Application Publication
(10) Pub. No.: US 2020/0393497 A1
(43) Pub. Date: Dec. 17, 2020

(54) DISPLAY DATA GENERATION DEVICE, DISPLAY DATA GENERATION METHOD, AND PROGRAM

(71) Applicant: Mitsubishi Electric Corporation, Tokyo (JP)

(72) Inventor: Osamu NASU, Tokyo (JP)

(73) Assignee: Mitsubishi Electric Corporation, Tokyo (JP)

(21) Appl. No.: 16/963,508

(22) PCT Filed: Feb. 16, 2018
(86) PCT No.: PCT/JP2018/005524

§ 371 Date: Jul. 21, 2020

(51) Int. Cl. G01R 13/34; G01R 13/32; G01R 13/02

(52) U.S. Cl. CPC G01R 13/345; G01R 13/02; G01R 13/32

(57) ABSTRACT

A display data generation device (10) includes: an acquisition unit (11) to acquire an input signal; a waveform generation module (161) (i) to extract, from waveform patterns predetermined as normal waveform patterns, a waveform pattern having the highest degree of similarity to the input signal for each interval of the input signal by using as the degree of similarity a degree to which waveforms are similar to each other and (ii) to generate a comparison waveform based on the waveform pattern extracted for each interval; and a data generation module (162) to generate and outputting display data for displaying a waveform of the input signal and the comparison waveform.

### TECHNICAL FIELD

The present disclosure relates to a display data generation device, a display data generation method, and a program.

### BACKGROUND ART

In a facility such as a factory, monitoring signals collected in the facility is commonly performed in order to promptly resolve an abnormality occurring in the facility. Therefore, applying a technique for monitoring signals and notifying a user of the occurrence of an abnormality to such a facility is conceivable (refer to, for example, Patent Literature 1).

Patent Literature 1 describes a device that overlaps a plurality of waveforms cut out from received digital signals and displays the overlapped waveforms. Since this device displays the overlapped waveforms obtained by overlapping both normal waveforms and abnormal waveforms without distinguishing between the normal and abnormal waveforms, the user can visually recognize the abnormal waveforms.

### CITATION LIST

### Patent Literature

Patent Literature 1: Unexamined Japanese Patent Application Kokai Publication No. 2007-333391

### SUMMARY OF INVENTION

### Technical Problem

The device disclosed in Patent Literature 1 is effective in a case in which the normal waveforms are uniformly determined. However, even in a situation where no abnormality occurs, signals collected in the facility generally vary in waveform due to various factors, and there is a case in which a plurality of waveforms may be allowed as a normal waveform. For this reason, when the device of Patent Literature 1 is used for monitoring an abnormality in a facility, normal waveforms of a plurality of patterns are overlapped and the overlapped waveforms are displayed, and thus the abnormal waveforms are difficult to recognize. Therefore, there is room to present a method for displaying waveforms enabling the user to easily recognize whether the waveforms are abnormal.

In order to solve the aforementioned problem, an objective of the present disclosure is to present waveforms in a manner enabling a user to easily recognize whether the waveform is abnormal.

### Solution to Problem

In order to achieve the aforementioned objective, a display data generation device according to the present disclosure includes: acquisition means for acquiring an input signal; waveform generation means for (i) extracting, from waveform patterns predetermined as normal waveform patterns, a waveform pattern having the highest degree of similarity to the input signal for each interval of the input signal by using a degree of similarity that is a degree to which waveforms are similar to each other and (ii) generating a comparison waveform based on the waveform pattern extracted for each interval; and data generation means for generating and outputting display data for displaying a waveform of the input signal and the comparison waveform.

### Advantageous Effects of Invention

According to the present disclosure, display data for displaying the waveform of the input signal and the comparison waveform is generated. The comparison waveform is generated from a waveform pattern similar to the input signal. Therefore, the comparison waveform has a shape close to the input signal and the shape is based on a predetermined waveform pattern. Accordingly, even if the waveform of the input signal changes to some extent in a situation where no abnormality occurs, the comparison waveform has a fixed shape. If such a comparison waveform is compared with the input signal, it is considered that the user can easily recognize the abnormal waveform of the input signal. Therefore, the waveform can be displayed such that the user can easily recognize whether there is an abnormality in the waveform.

### BRIEF DESCRIPTION OF DRAWINGS

FIG. 1 is a diagram illustrating a functional configuration of a display data generation device according to an embodiment of the present disclosure;

FIG. 2 is a diagram illustrating a hardware configuration of the display data generation device according to the embodiment;

FIG. 3 is a flow chart illustrating display data generation processing according to the embodiment;

FIG. 4 is a flow chart illustrating learning processing according to the embodiment;

FIG. 5 is a diagram for explaining the learning processing according to the embodiment;

FIG. 6 is a diagram for explaining processing of an input signal and a determination as to whether there is an abnormality in the input signal according to the embodiment;

FIG. 7 is a diagram for explaining a way of determining an abnormality in the embodiment;

FIG. 8 is a diagram illustrating an example of a display screen according to the embodiment;

FIG. 9 is a flow chart illustrating waveform generation processing according to the embodiment;

FIG. 10 is a diagram for explaining synthesis of synthesis patterns according to the embodiment;

FIG. 11 is a diagram illustrating the display data generation device according to a modified example;

FIG. 12 is a first diagram illustrating synthesis of synthesis patterns in the modified example; and

FIG. 13 is a second diagram illustrating synthesis of the synthesis patterns in the modified example.

### DESCRIPTION OF EMBODIMENTS

A display data generation device 10 according to an embodiment of the present disclosure is described below in detail with reference to drawings.

### Embodiment

The display data generation device 10 according to the present embodiment is a factory automation (FA) device installed in a factory and is included in a production system that produces products. This production system has a function of using sensors to monitor a plurality of types of workpieces flowing on a production line. The display data generation device 10 acquires outputs of the sensors, and when an abnormality occurs, the display data generation device 10 displays to a user, in addition to signals actually output from the sensors, a signal that is supposed to be displayed when there is no abnormality, thereby presenting to the user a signal corresponding to the abnormality in an easily understandable way.

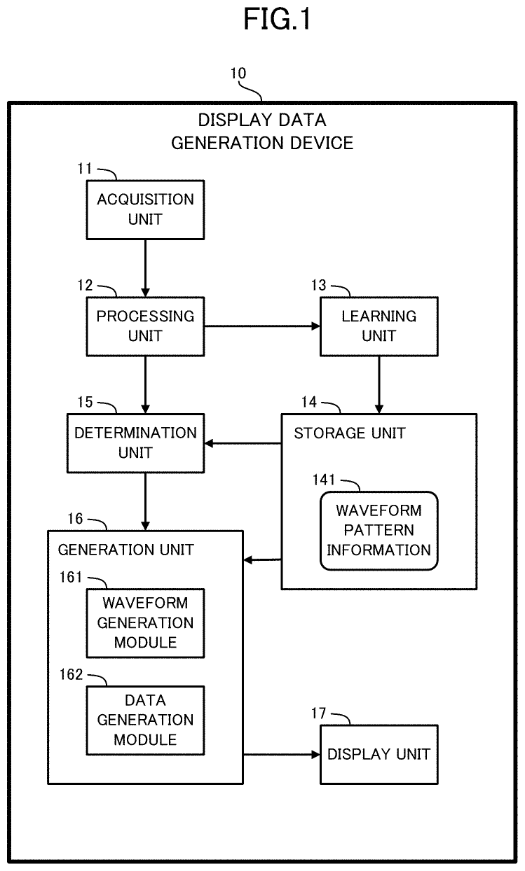

Operation modes of the display data generation device 10 include (i) an analysis mode for analyzing a signal during normal operation and detecting an abnormality and (ii) a learning mode for learning a normal waveform pattern as preparation for detecting the abnormality. In order to make the display data generation device 10 operate in these operation modes, as illustrated in FIG. 1, the display data generation device 10 includes, as a function, (i) an acquisition unit 11 to acquire a signal, (ii) a processing unit 12 to process the signal, (iii) a learning unit 13 to learn normal signal waveform patterns, (iv) a storage unit 14 to store waveform pattern information 141 indicating the normal waveform patterns, (v) a determination unit 15 to determine whether or not there is an abnormality in the signal, (vi) a generation unit 16 to generate display data for displaying a waveform of the signal, and (vii) a display unit 17 to display the waveform of the signal based on the display data.

The acquisition unit 11 includes an input terminal for inputting a signal from the exterior of the display data generation device 10. The acquisition unit 11 acquires the signal input from outside of the display data generation device 10 and transmits the signal to the processing unit 12. Hereinafter, a signal acquired by the acquisition unit 11 in the learning mode is referred to as a learning signal, and a signal acquired by the acquisition unit 11 in the analysis mode is referred to as an input signal. These signals acquired by the acquisition unit 11 are digital signals and are signals indicating time-series voltage values sampled at fixed intervals. The fixed interval is, for example, 1 ms, 10 ms, or 100 ms. The acquisition unit 11 functions as acquisition means specified in the Claims.

The processing unit 12 performs processing such as noise removal on the signal received from the acquisition unit 11. The processing by the processing unit 12 is executed as preprocessing for (i) learning performed by the learning unit 13 described later and (ii) a determination made by the determination unit 15. The processing unit 12 processes the learning signal, transmits the processed learning signal to the learning unit 13, processes the input signal, and transmits the processed input signal to the determination unit 15.

The learning unit 13 learns a normal pattern from a waveform of the learning signal received from the processing unit 12. Usually, in a production system, a signal indicating the output of a sensor has a plurality of waveforms having normal patterns corresponding to a sensing target. The learning unit 13 classifies the waveform of the learning signal having such a waveform and stores a classification result in the storage unit 14 as waveform pattern information 141 indicating a normal pattern. The learning unit 13 functions as learning means specified in the Claims.

The storage unit 14 stores the waveform pattern information 141 stored by the learning unit 13 and supplies the waveform pattern information 141 to the determination unit 15 and the generation unit 16 as necessary.

The determination unit 15 determines, based on the waveform pattern information 141, whether the input signal received from the processing unit 12 is abnormal. Specifically, the determination unit 15 (i) determines that the waveform of the input signal is normal when the waveform of the input signal is similar to one of the waveform patterns indicated by the waveform pattern information 141 or (ii) determines that the waveform of the input signal is abnormal when the waveform of the input signal is not similar to any of waveform patterns indicated by the waveform pattern information 141. The determination unit 15 transmits the input signal and a determination result to the generation unit 16. The determination unit 15 functions as determination means specified in the Claims.

The generation unit 16 includes (i) a waveform generation module 161 to generate a comparison waveform with which the waveform of the input signal is compared and (ii) a data generation module 162 to generate display data for displaying the waveform of the input signal, the comparison waveform, and the determination result by the determination unit 15. The comparison waveform is a waveform obtained by inferring, from the normal waveform patterns indicated in the waveform pattern information 141, a normal waveform of a signal supposed to be displayed when there is no abnormality.

The waveform generation module 161 generates the comparison waveform from (i) the input signal received from the determination unit 15 and (ii) the waveform pattern information 141 read from the storage unit 14. Specifically, the waveform generation module 161 synthesizes a synthesis pattern by combining waveform patterns similar to the input signal and generates the comparison waveform by sequentially executing this synthesis. The waveform generation module 161 does not use the result of the determination made by the determination unit 15 when generating the comparison waveform. The waveform generation module 161 functions as waveform generation means specified in the Claims.

The data generation module 162 generates display data for displaying, side by side, the waveform of the input signal received from the determination unit 15, the comparison waveform generated by the waveform generation module 161, and the determination result by the determination unit 15. The data generation module 162 outputs the generated display data to the display unit 17. The data generation module 162 functions as data generation means specified in the Claims.

The display unit 17 displays to the user a screen image generated using the display data output from the generation unit 16.

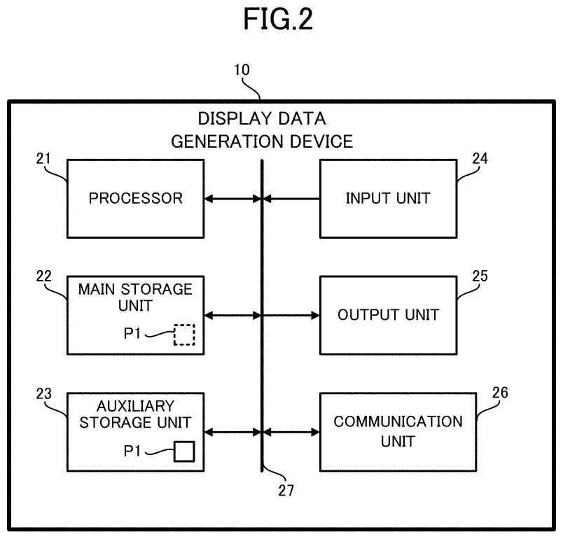

In order to achieve the above-described functions, as illustrated in FIG. 2, the display data generation device 10 includes, as a hardware configuration, a processor 21, a main storage unit 22, an auxiliary storage unit 23, an input unit 24, an output unit 25, and a communication unit 26. The main storage unit 22, the auxiliary storage unit 23, the input unit 24, the output unit 25, and the communication unit 26 are connected to the processor 21 via an internal bus 27.

The processor 21 includes a micro processing unit (MPU). The processor 21 realizes various functions of the display data generation device 10 by executing a program P1 stored in the auxiliary storage unit 23 and executes processing described below.

The main storage unit 22 includes a random access memory (RAM). The program P1 is loaded from the auxiliary storage unit 23 into the main storage unit 22. The main storage unit 22 is used as a work area for the processor 21.

The auxiliary storage unit 23 includes a nonvolatile memory such as an electrically erasable programmable read-only memory (EEPROM). The auxiliary storage unit 23 stores various types of data used for processing by the processor 21 in addition to the storing of the program P1. The auxiliary storage unit 23 supplies, to the processor 21, data to be used by the processor 21 and stores data supplied from the processor 21 in accordance with instructions from the processor 21.

The input unit 24 includes an input device such as input keys and a pointing device. The input unit 24 acquires information input by the user of the display data generation device 10 and notifies the processor 21 of the acquired information.

The output unit 25 includes output devices such as a liquid crystal display (LCD) and a speaker. The output unit 25 presents various types of information to the user in accordance with instructions from the processor 21.

The communication unit 26 includes an input terminal or a network interface circuit for communicating with an external device. The communication unit 26 receives a signal from the outside and outputs, to the processor 21, data of a voltage value indicated by this signal. Also, the communication unit 26 may transmit, to the external device, a signal indicating data output from the processor 21.

Among these components of the hardware configuration, the processor 21 realizes the processing unit 12, the learning unit 13, the determination unit 15, and the generation unit 16 that are illustrated in FIG. 1. At least one of the main storage unit 22 or the auxiliary storage unit 23 realizes the storage unit 14. The output unit 25 realizes the display unit 17. The communication unit 26 realizes the acquisition unit 11.

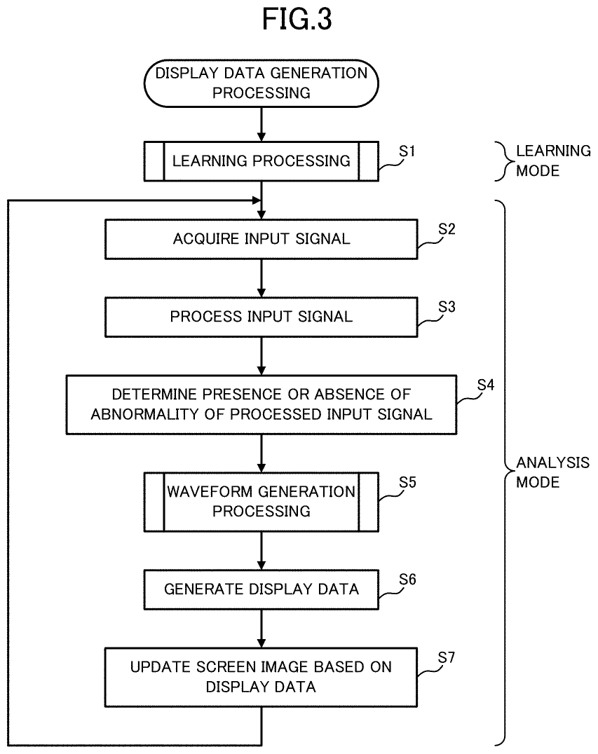

Subsequently, display data generation processing executed by the display data generation device 10 is described in detail with reference to FIGS. 3 to 10. The display data generation processing illustrated in FIG. 3 starts upon turning the display data generation device 10 on or in accordance with an operation by the user.

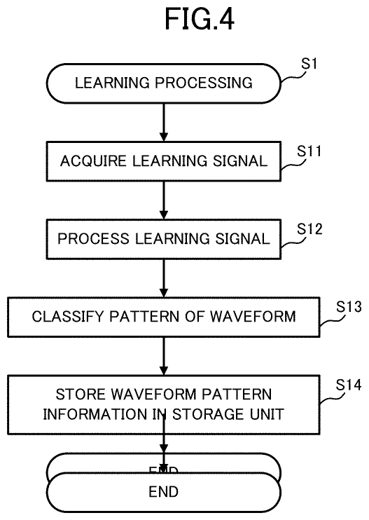

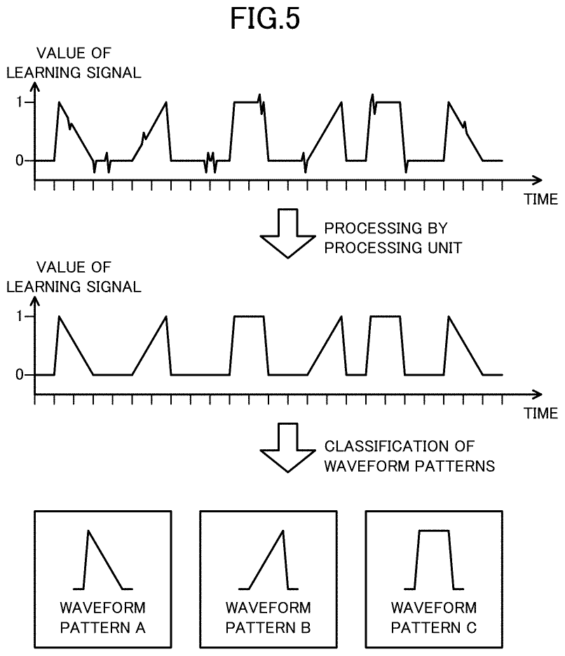

In the display data generation processing, the display data generation device 10 executes learning processing (step S1). The execution of the learning processing is equivalent to operation in the learning mode. The details of the learning processing are described below with reference to FIGS. 4 and 5.

In the learning processing illustrated in FIG. 4, the acquisition unit 11 acquires the learning signal (step S11). Specifically, the acquisition unit 11 acquires the learning signal input to the input terminal by the user. The learning signal is a signal prepared in advance by the user and this signal has a normal waveform pattern. An example of the learning signal is illustrated in the upper portion of FIG. 5. As illustrated in FIG. 5, a certain amount of noise is included in the learning signal due to a factor such as a contact state of the input terminal or an electromagnetic noise.

Again with reference to FIG. 4, after step S11, the processing unit 12 processes the learning signal (step S12). For example, as illustrated in the middle portion of FIG. 5, the processing unit 12 removes noise by smoothing or by filtering high-frequency components included in the learning signal.

Next, the learning unit 13 classifies the waveform patterns of the learning signal processed by the processing unit 12 (step S13). Specifically, the learning unit 13 uses a so-called pattern recognition technique to classify the waveform pattern included in the learning signal. The pattern recognition technique is, for example, a support vector machine (SVM) or deep learning of a neural network. Three waveform patterns A, B, and C classified by the learning unit 13 are illustrated in the lower portion of FIG. 5.

Again with reference to FIG. 4, after step S13, the learning unit 13 stores, in the storage unit 14, the waveform pattern information 141 indicating the waveform patterns obtained by the learning processing (step S14). As a result, the waveform pattern information 141 indicating waveform patterns as normal waveform patterns is determined in advance prior to operation in the analysis mode described below. The format of the waveform pattern information 141 may be a format indicating a series of values at a plurality of sampling points for each waveform pattern or may be another format. Thereafter, the learning processing ends.

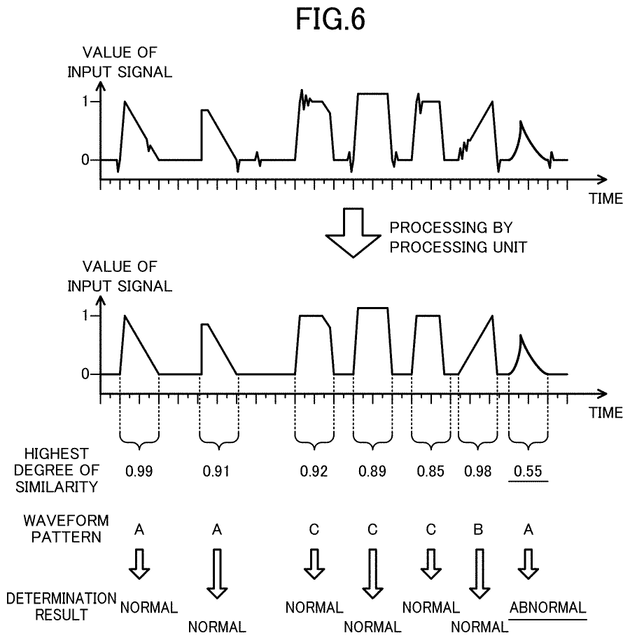

Again with reference to FIG. 3, after the learning processing in step S1, the display data generation device 10 starts operating in the analysis mode. That is, the acquisition unit 11 acquires the input signal (step S2). Specifically, the acquisition unit 11 acquires the input signal input to the input terminal by the user. This input signal is a signal indicating an output value of a sensor installed on the production line and is used for monitoring the occurrence of an abnormality in the production line. As illustrated in the upper portion of FIG. 6, like the learning signal, the input signal includes a certain amount of noise.

Next, the processing unit 12 processes the input signal (step S3). This processing is processing that is equivalent to the processing performed on the learning signal in the learning processing. As a result, the noise is removed from the input signal as illustrated in the middle portion of FIG. 6. As can be seen from FIG. 6, the waveform of the input signal does not necessarily match a normal waveform pattern and may have a distorted shape due to a factor such as a disturbance on the production line. However, in many cases, the waveform of the input signal has a shape similar to a normal waveform pattern. When an abnormality occurs in the production line, the waveform of the input signal becomes significantly different from the normal waveform pattern, and this abnormality must be notified to the user.

Again with reference to FIG. 3, after step S3, the determination unit 15 determines whether the processed input signal is abnormal (step S4). Specifically, the determination unit 15 calculates a degree of similarity between the input signal and each of the waveform patterns indicated by the waveform pattern information 141. The degree of similarity means a degree to which waveforms is similar to each other. The determination unit 15 determines that processed input signal is normal and thus is not abnormality if the highest degree of similarity of the calculated degrees of similarity exceeds a threshold. On the other hand, the determination unit 15 determines that the processed input signal is abnormal if the highest degree of similarity is below the threshold.

The results of determinations made by the determination unit 15 are schematically illustrated in the lower portion of FIG. 6. Specifically, FIG. 6 illustrates, in order, (i) the “highest degrees of similarity” of the degrees of similarity calculated for the waveform patterns by the determination unit 15, (ii) determination results as to which of the waveform patterns A, B, and C a waveform pattern for which the highest degrees of similarity is calculated is, and (iii) determination results as to whether each of the waveform patterns are normal or abnormal.

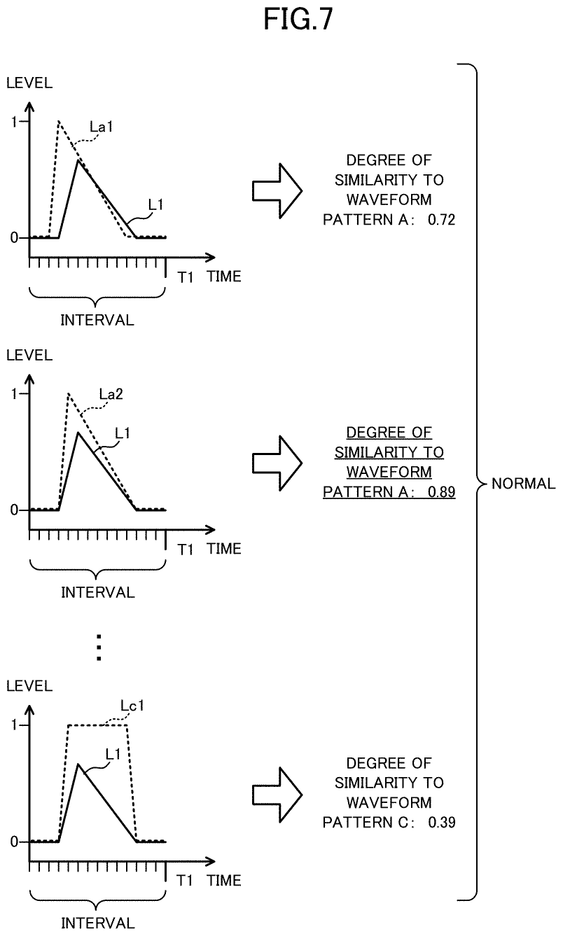

The determination by the determination unit 15 is described in more detail with reference to FIG. 7. FIG. 7 illustrates an example in which a degree of similarity between the input signal and the waveform pattern is calculated at a time T1 that is the current time. A solid line L1 in FIG. 7 indicates the input signal, and a broken line La1 indicates a waveform pattern A arranged during a fixed interval extending to the current time. Also, a broken line La2 indicates the waveform pattern A arranged at a time different from the broken line La1 in this interval. Specifically, the broken line La2 indicates a pattern obtained by shifting the waveform pattern of the broken line La1 by one sampling period. Also, a broken line Lc1 indicates a waveform pattern C arranged during this interval. The width of the interval is a predetermined width, and is preferably wider than the maximum width among the widths of the waveform patterns.

As illustrated in FIG. 7, the determination unit 15 calculates a degree of similarity between: each of the waveform patterns; and the input signal each time when each of the waveform patterns is shifted. This degree of similarity is calculated as a value based on the sum of square errors between the input signal and each of the waveform patterns at all sampling points in the interval. For example, when a value of the input signal at a time t is L(t), a value at the time t of the waveform pattern arranged in the interval is W (t), and the degree of similarity is D, this degree of similarity D is calculated using the following equation (1). A symbol/indicates the total sum over all times tin the interval.

D=1/(1+Σ(L(t)−W(t))²) (1)

According to the above-described equation (1), the degree of similarity D is a value in the range from 0 to 1. The degree of similarity is 1 for a waveform pattern that completely matches the input signal. For this reason, the similarity evaluated by the degree of similarity includes the case where the waveforms completely match the wave form of the input signal. A technique for calculating the degree of similarity is not limited to the above-described equation (1) and the above-described equation (1) may be optionally changed to another one.

As illustrated in FIG. 7, the determination unit 15 determines whether the highest degree of similarity of the calculated degrees of similarity exceeds the threshold. The threshold is, 0.8, for example. In FIG. 7, since the highest degree of similarity between the input signal and the waveform pattern A arranged at a certain position in the interval is calculated as 0.89, the determination unit 15 determines that the input signal is normal. Here, the waveform pattern having the highest degree of similarity is considered to be a waveform that the input signal should originally have. The determination unit 15 performs the above-described determination processing at all sampling times.

Again with reference to FIG. 3, after step S4, the display data generation device 10 executes waveform generation processing (step S5). In the waveform generation processing, the waveform generation module 161 of the generation unit 16 generates a comparison waveform with which the waveform of the input signal is compared. Details of the waveform generation processing are described below.

Next, the generation unit 16 generates display data (step S6). Specifically, the data generation module 162 generates display data for displaying, side by side, (i) the waveform of the input signal, (ii) the comparison waveform generated in step S5, and (iii) the determination results obtained in step S4.

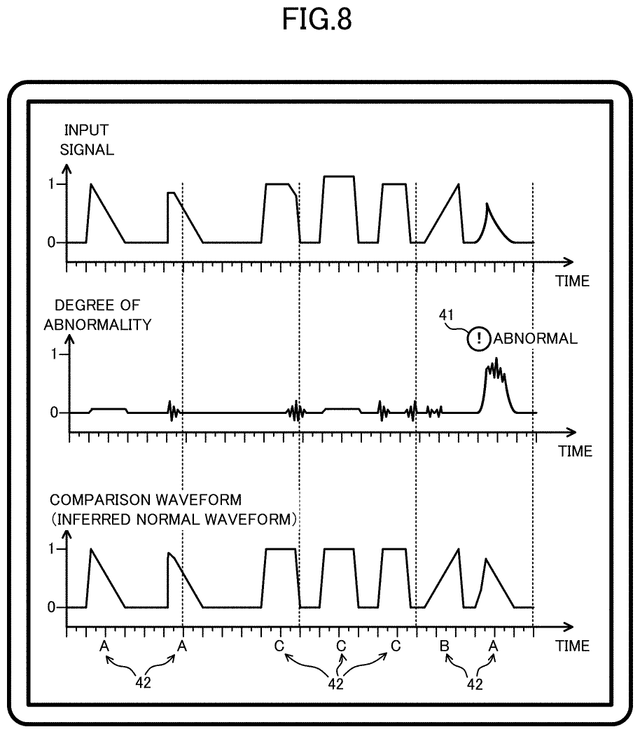

FIG. 8 illustrates an example of a screen image displayed based on this display data. As illustrated in FIG. 8, this screen image includes a waveform of the processed input signal, a degree of abnormality corresponding to the degree of similarity, and the comparison waveform. Additionally, this screen image includes an icon 41 indicating, as the determination result obtained in step S4, an “abnormality” determination result. Additionally, this screen image includes an identifier 42 indicating the waveform pattern for which the highest degree of similarity is calculated in step S4. Accordingly, the user can easily discriminate an abnormal portion of the waveform of the input signal and can easily compare the waveform of the input signal with the comparison waveform.

When the degree of similarity D is calculated by the equation (1), the abnormality degree F. can be calculated by using a equation F=1−D. The degree of abnormality indicates a degree to which the waveform of the input signal deviates from the normal waveform patterns and the input signal is abnormal. However, a method of calculating the degree of abnormality is not limited to this, and the above-described method may be optionally changed to another method. Further, the screen image displayed based on the display data may include the degree of similarity instead of the degree of abnormality or may include the degree of similarity in addition to the degree of abnormality.

Again with reference to FIG. 3, after step S6, the display data generation device 10 updates the screen image based on the display data (step S7). Specifically, the display unit 17 updates the screen image so as to indicate the contents of the display data generated in step S6.

Afterward, the display data generation device 10 shifts the processing to step S2. For this reason, results of analysis of the input signal sequentially input to the display data generation device 10 are displayed in real time. As a result, the user can observe the presence or absence of abnormality at the current time in the production line.

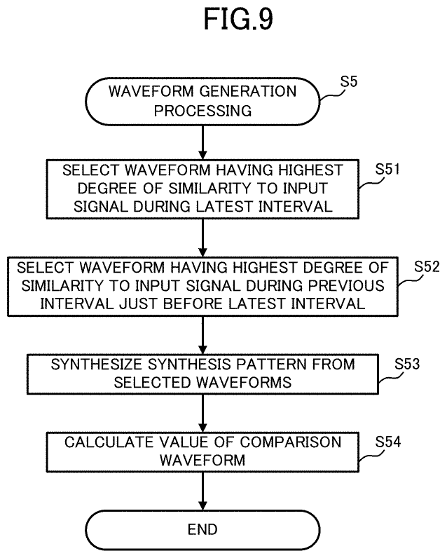

Subsequently, the details of the waveform generation processing in step S5 is described with reference to FIG. 9. In the waveform generation process, the waveform generation module 161 selects a waveform pattern having the highest degree of similarity to the input signal in the latest interval (step S51). Specifically, the waveform generation module 161 selects, from the waveform patterns A, B, and C indicated by the waveform pattern information 141, the waveform pattern having the highest degree of similarity to a portion of the input signal that (i) is cut out from the input signal and (ii) is located in the latest interval. The waveform generation module 161 calculates the degree of similarity each time when each of the waveform patterns A, B, and C is shifted in the time axis direction, as in the calculation of the degree of similarity by the determination unit 15, and then the waveform generation module 161 searches the waveform pattern having the highest degree of similarity and its arrangement. The latest interval is a time interval having a width equivalent to the width of the interval to be used by the determination unit 15.

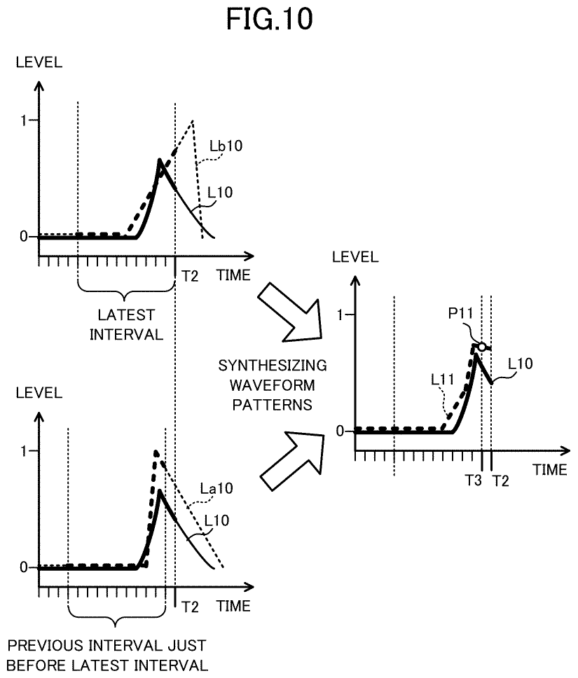

The upper left portion of FIG. 10 illustrates the input signal and the waveform pattern B that has the highest degree of similarity to the input signal during the latest interval extending to a time T2 that is the current time. A line L10 indicates the input signal, and a line Lb10 indicates the waveform pattern B arranged so that the waveform pattern B has the highest degree of similarity. A portion of the line Lb10 included in the latest interval is indicated by a thick broken line, and the other portion of the line Lb10 is indicated by a thin broken line.

Again with reference to FIG. 9, after step S51, the waveform generation module 161 selects a waveform pattern having the highest degree of similarity to the input signal during a previous interval just before the latest interval (step S52). This waveform pattern is selected in a manner similar to that in step S51. That is, the waveform generation module 161 selects, from the waveform patterns A, B, and C, a waveform pattern having the highest degree of similarity to the portion of the input signal that (i) is cut out from the input signal and (ii) is located during the previous interval.

In the lower left portion of FIG. 10, FIG. 10 illustrates the input signal and the waveform pattern A that has the highest degree of similarity to the input signal during the previous interval just before the latest interval. An interval obtained by shifting the latest interval by one sampling period corresponds to the previous interval. A line La10 in FIG. 10 indicates the waveform pattern A arranged so that the waveform pattern A has the highest degree of similarity. A portion of the line La10 included in the interval is indicated by a thick broken line, and the other portion of the line La10 is indicated by a thin broken line.

As illustrated in the upper left portion and the lower left portion of FIG. 10, the waveform pattern having the highest degree of similarity to the input signal is extracted for each of the intervals of the input signal, from the predetermined normal waveform patterns.

Again with reference to FIG. 9, after step S52, the waveform generation module 161 synthesizes a synthesis pattern from the waveform patterns selected in steps S51 and S52 (step S53). Specifically, as illustrated in the right area of FIG. 10, the waveform generation module 161 obtains an average value of the waveform pattern indicated by the line La10 and the waveform pattern indicated by the line Lb10 at each sampling time, thereby calculating the synthesis pattern. In FIG. 10, the calculated synthesis pattern is indicated by a line L11. As can be seen from FIG. 10, the synthesis pattern is a pattern that approximates the waveform of the input signal based on the combination of the waveform patterns A and B. For this reason, even if the waveform of the input signal cannot be distinguished from either of the waveform pattern A or B, the synthesis pattern is understood to be a pattern obtained by estimating, from the waveform patterns A and B, the shape that the input signal should have.

In FIG. 10, the waveform pattern having the highest degree of similarity during the latest interval is different from the waveform pattern having the highest degree of similarity during the previous interval. However, when the input signal has a shape matching one of the normal waveform patterns, the waveform of the input signal is fitted by the same normal waveform pattern both in the latest interval and in the previous interval. Since the average of these waveform patterns is equal to this normal waveform pattern, the synthesis pattern is a single normal waveform pattern.

Again with reference to FIG. 9, after step S53, the waveform generation module 161 calculates a value of the comparison waveform (step S54). Specifically, the waveform generation module 161 adopts, as the value of the comparison waveform, a value that the synthesis pattern indicated in the right portion of FIG. 10 has at a time T3 that is earlier than the time T2 by one sampling period. In FIG. 10, the value of a point P11 corresponds to the value of the comparison waveform.

Again with reference to FIG. 9, when step S54 ends, the waveform generation module 161 ends the waveform generation processing.

As illustrated in FIG. 3, the display data generation device 10 repeatedly performs waveform generation processing. For this reason, in the waveform generation processing, a value of the comparison waveform is calculated every time a new value of the input signal is obtained. As a result, when the screen image displayed by the display unit 17 is updated, a new value of the comparison waveform is displayed. Therefore, by repeating the waveform processing, time series values of the comparison waveform are sequentially calculated, and a comparison waveform is generated from a waveform pattern extracted from the input signal during each interval.

As described above, the display data generation device 10 generates display data for displaying the waveform of the input signal and the comparison waveform. The comparison waveform is generated by synthesizing a synthesis pattern from a waveform pattern similar to the waveform of the input signal. Therefore, the comparison waveform has a shape close to the shape of the input signal and this shape is based on the predetermined waveform patterns. As a result, even if the waveform of the input signal changes to some extent in a situation where no abnormality occurs, the comparison waveform has a fixed shape. If such a comparison waveform is compared with the input signal, the user is considered to be able to easily recognize the abnormal waveform of the input signal. Therefore, the display data generation device 10 can present a screen image enabling the user to easily recognize whether there is an abnormality in the waveform.

Also, the determination unit 15 determines, for the waveform pattern having the highest degree of similarity to the input signal, whether this highest degree of similarity is equal to or greater than the threshold. In other words, the determination unit 15 determines, for each portion cut out from the input signal at the interval, whether a degree of similarity between each portion cut out from the input signal and every waveform pattern indicated by the waveform pattern information 141 is lower than the threshold. The display data generated by the display data generation device 10 is data for displaying the determination results obtained by the determination unit 15 as to the presence or absence of abnormality in addition to the waveform of the input signal and the comparison waveform. For this reason, the user can reliably recognize the presence or absence of abnormality of a signal. As a result, the user can quickly achieve a recovery from an abnormal state and easily find the cause of the abnormality.

Also, the display data generation device 10 includes the learning unit 13 that learns the normal patterns. By learning the normal patterns, the comparison waveform attains a shape that matches the normal waveform pattern when there is no abnormality in the input signal. If the input signal is abnormal, the comparison waveform, in a range similar to the input signal, attains a shape that the input signal is supposed to have when the input signal is not abnormal. In other words, the comparison waveform can be regarded as a normal waveform inferred from the input signal. For this reason, it is expected that the user will be able to easily recognize the abnormality by referring to the comparison waveform.

Also, the display data generation device 10 repeats the processing in steps S2 to S7 as illustrated in FIG. 3. As a result, the waveform generation module 161 repeats the synthesis of a synthesis pattern for a combination of one interval and another interval among intervals that are sequentially defined so that a former interval overlaps a next interval just after the former interval. As a result, a comparison waveform can be generated in real time for the input signal.

Also, as illustrated in FIG. 10, the value of the comparison waveform is a value of the synthesis pattern and is a value included in a range in which two intervals in which degrees of similarity are calculated for synthesis overlap each other. Since the synthesis pattern can be considered to be particularly fitted to the input signal in this overlapping range, a more accurate comparison waveform is considered to be able to be obtained.

Although the embodiment of the present disclosure is described above, the present disclosure is not limited to the above-described embodiment.

For example, although the display data generation device 10 is installed in a factory, the display data generation device 10 may be installed in a facility other than a factory. Moreover, although the display data generation device 10 is included in the production system, the display data generation device 10 may be included in a manufacturing system, a processing system, an inspection system, or another system. Alternatively, the display data generation device 10 may be an independent device without being included in a system. Furthermore, the signal input to the display data generation device 10 is a time-series signal of the output value of the sensor. However, the present disclosure is not limited to this, and it is sufficient as long as the signals used for the present disclosure indicate a pattern.

Also, the learning signal and the input signal are not limited to digital signals. In a case in which the learning signal and the input signal are analog signals, when the processing unit 12 performs an analog-to-digital (A/D) conversion, the display data generation device 10 can be configured to be equivalent to the above-described embodiment.

Additionally, although the example in which the acquisition unit 11 acquires the learning signal and the input signal input from the outside to the input terminal and the display data is updated in real time with respect to the input signal is described above, the present disclosure is not limited to this. The acquisition unit 11 may acquire the learning signal and the input signal by reading data whose address is specified by the user and display data may be generated by batch processing for the input signal.

Additionally, although the display data generation device 10 generates the waveform pattern information 141 by the learning processing performed by the learning unit 13, the present disclosure is not limited to this. The display data generation device 10 may be configured without the learning unit 13 and the waveform pattern information 141 stored in the storage unit 14 may be used by the user.

Also, as illustrated in FIG. 3, the display data generation device 10 operates in the analysis mode after the processing in the learning mode is completed. However, the present disclosure is not limited to this. The display data generation device 10 may generate the waveform pattern information 141 by estimating a normal waveform pattern from the input signal without receiving the learning signal. That is, the display data generation device 10 may execute the learning mode processing and the analysis mode processing in parallel.

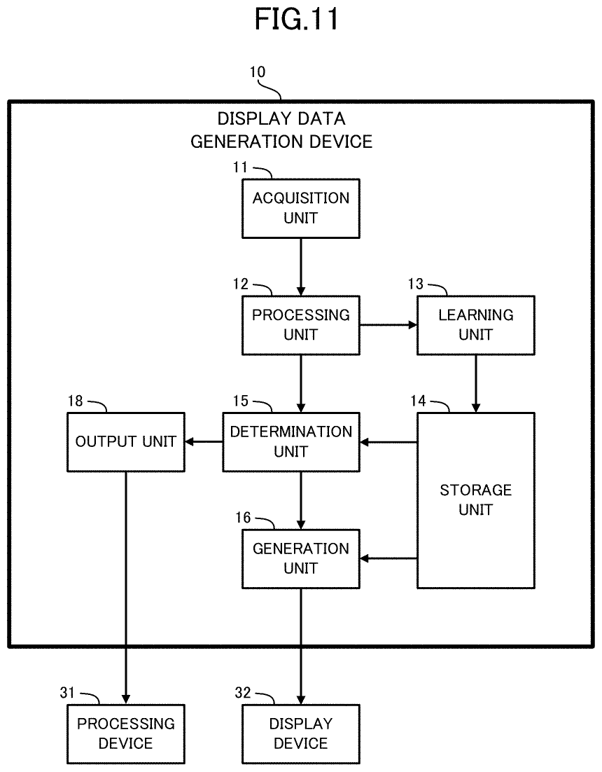

Also, as illustrated in FIG. 11, the display data generation device 10 may be configured without the display unit 17, and the generation unit 16 may transmit the display data to the external display device 32. Additionally, the display data generation device 10 may include an output unit 18 that outputs a determination result obtained by the determination unit 15 to the outside, and the output unit 18 may output the determination result to an external processing device 31 executing processing that then uses the determination result.

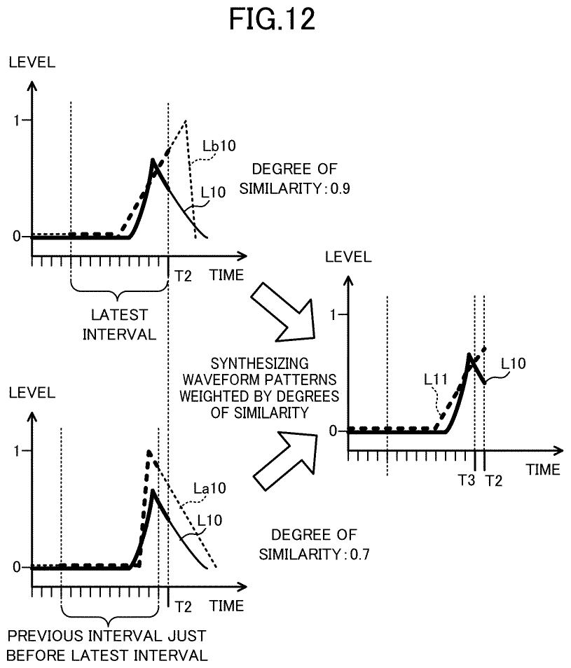

Also, a method of synthesizing the synthesis pattern is not limited to a method performed by taking the average of the waveform patterns as illustrated in FIG. 10, and such a technique may be optionally changed to another technique. For example, synthesizing the synthesis pattern from the waveform patterns based on the degree of similarity is conceivable. FIG. 12 illustrates an example in which waveform patterns are synthesized by weighting the waveform patterns by the degrees of similarity that are calculated in order to select the waveform patterns. In the example of FIG. 12, the synthesis pattern has a shape more similar to the input signal as compared to the example of FIG. 10.

The method of synthesizing the synthesis pattern includes adopting one of the waveform patterns. For example, a waveform pattern having a high degree of similarity may be used as a synthesis pattern as is.

Also, in the above-described embodiment, the value of the synthesis pattern in the range where intervals overlap each other is used as the value of the comparison waveform. However, a value outside the overlapping range may be used.

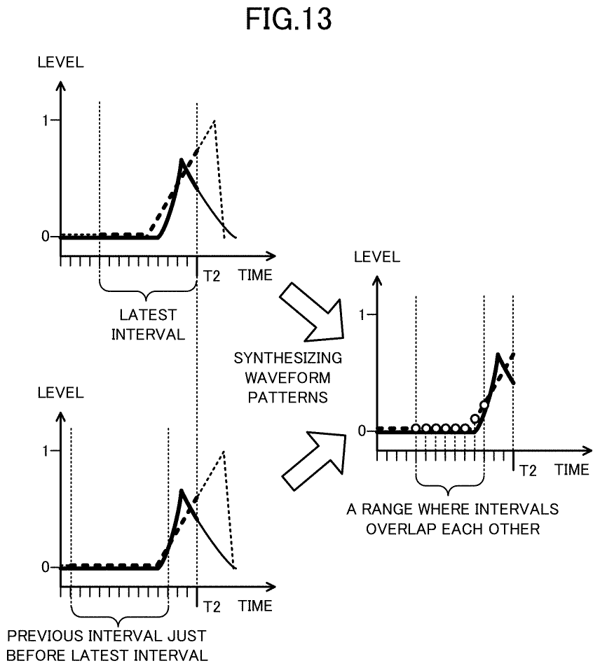

In the above-described embodiment, as illustrated in FIG. 10, among the values constituting the synthesis pattern, the last sampling value in the range where the intervals overlap each other is used as the value of the comparison waveform. However, the present disclosure is not limited to this. For example, as indicated by outline circles in FIG. 13, all sampling values in the range where the intervals overlap each other may be used as the values of the comparison waveform. In this case, a new value is used at some sampling time each time when the synthesis pattern is synthesized.

In the above-described embodiment, the previous interval is an interval obtained by shifting the latest interval back by one sampling period. However, the present disclosure is not limited to this. That is, an amount by which the interval is shifted may be optionally changed to another amount, and the width of the portion where the intervals overlap each other may be optionally set.

In addition, although two intervals are defined for synthesizing the synthesis pattern, the present disclosure is not limited to this. The waveform generation module 161 may synthesize a synthesis pattern from waveform patterns similar to the input signal in each of three or more intervals.

In the above-described embodiment, the case where the intervals overlap each other is described. However, if the intervals do not overlap each other, the comparison waveform may be formed by connecting waveform patterns each having the highest degree of similarity in each interval without synthesizing the synthesis pattern.

In the above-described embodiment, steps S2 to S7 illustrated in FIG. 3 are repeated each time when a new sampling value of the input signal is input. However, the present disclosure is not limited to this. That is, it is not necessary to synchronize the sampling period and iterative processing in steps S2 to S7.

Also, the functions of the display data generation device 10 can be realized by dedicated hardware or by a normal computer system.

For example, the program P1 executed by the processor 21 is stored in a non-transitory computer-readable recording medium, the recording medium storing the program P1 is distributed, and the program P1 is installed in the computer, thereby configuring a device that executes the above-described processing. For example, a flexible disk, a compact disc-read-only memory (CD-ROM), a digital versatile disc (DVD), and a magneto-optical disc (MO) can be considered as such a recording medium.

Also, the program P1 may be stored in a disk device included in a server device on a communication network such as the Internet and may be downloaded onto a computer, for example, by superimposing the program on a carrier wave.

Also, the above-described processing can be achieved by starting and executing the program P1 while transferring the program P1 through the communication network.

Additionally, the above-described processing can also be achieved by executing all of or a portion of the program P1 on the server device and executing the program while the computer are transmitting and receiving information on the processing via the communication network.

When the above-described functions are realized (i) by sharing tasks with an operating system (OS) or (ii) by cooperation between the OS and an application, only portions of the program P1 other than a portion of the program P1 executed by the OS may be stored in the medium and the medium may be distributed. Alternatively, such portions of the program P1 may be downloaded to a computer.

Also, the means for realizing the functions of the display data generation device 10 is not limited to software, and a part of or all of the functions may be realized by dedicated hardware including a circuit.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

The present disclosure is suitable for monitoring the presence or absence of an abnormality.

### REFERENCE SIGNS LIST

10 Display data generation device
11 Acquisition unit
12 Processing unit
13 Learning unit
14 Storage unit
141 Waveform pattern information
15 Determination unit
16 Generation unit
161 Waveform generation module
162 Data generation module
17 Display unit
18 Output unit
21 Processor
22 Main storage unit
23 Auxiliary storage unit
24 Input unit
25 Output unit
26 Communication unit
27 Internal bus
31 Processing device
32 Display device
41 Icon
42 Identifier
L1 Solid line
La1, La2, Lc1 Broken line
L10, L11, La10, Lb10 Line
P1 Program
P11 Point

1. A display data generation device comprising:
an acquirer to acquire an input signal;
a waveform generator to (i) extract, from waveform patterns predetermined as normal waveform patterns, a waveform pattern having a highest degree of similarity to the input signal for each interval of the input signal by using a degree of similarity that is a degree to which waveforms are similar to each other and (ii) generate a comparison waveform based on the waveform pattern extracted for each interval; and
a data generator to generate and output display data for displaying a waveform of the input signal and the comparison waveform.

2. The display data generation device according to claim 1, wherein
intervals are subsequently defined such that each of the intervals overlaps an interval of the intervals that is adjacent to each of the intervals, and
the waveform generator generates the comparison waveform by repeating, for one interval of the intervals and an interval of the intervals that is adjacent to the one interval, a process in which a synthesis pattern is synthesized from (i) a first waveform pattern among the waveform patterns that has a highest degree of similarity to a portion of the input signal cut out from the input signal during a first interval and (ii) a second waveform among the waveform patterns that has a highest degree of similarity to a portion of the input signal cut out from the input signal during a second interval overlapping the first interval.

3. The display data generation device according to claim 1, further comprising:
a determiner to determine, for each of the intervals, whether the degree of similarity between the input signal and each of the waveform patterns is less than a threshold,
wherein the data generator generates and outputs display data for displaying the waveform of the input signal, the comparison waveform, and a result of the determination made by the determiner.

4. The display data generation device according to claim 1, further comprising:
learning means for learning a learner to learn the waveform patterns from a learning signal having waveforms that indicate different types of patterns.

5. The display data generation device according to claim 1, wherein the waveform generator generates the comparison waveform based on the degree of similarity of the waveform patterns extracted during the respective intervals.

6. The display data generation device according to claim 2, wherein the waveform generator synthesizes, from the first waveform pattern and the second waveform pattern, the synthesis pattern in a range where the first interval and the second interval overlap each other.

7. A method of generating display data, the method comprising:
an acquisition step of acquiring an input signal;
a waveform generation step of (i) extracting, from waveform patterns predetermined as normal waveform patterns, a waveform pattern having a highest degree of similarity to the input signal for each interval of the input signal by using a degree of similarity that is a degree to which waveforms are similar to each other and (ii) generating a comparison waveform from the waveform pattern extracted for each interval; and
a data generation step of generating and outputting display data for displaying the waveform of the input signal and the comparison waveform.

8. A non-transitory computer-readable recording medium storing a program for causing a computer to:
acquire an input signal;
extract, from waveform patterns predetermined as normal waveform patterns, a waveform pattern having a highest degree of similarity to the input signal for each interval of the input signal by using a degree of similarity that is a degree to which waveforms are similar to each other;
generate a comparison waveform from the waveform pattern extracted for each interval; and
generate and output display data for displaying the waveform of the input signal and the comparison waveform.
